(19) United States
(12) Patent Application Publication
(10) Pub. No.: US 2025/0311382 A1
(43) Pub. Date: Oct. 2, 2025

(54) Cellular Wafer Structure

(71) Applicant: Wolfspeed, Inc., Durham, NC (US)

(72) Inventors: Craig William Hardin, Apex, NC (US); Adam Benjamin Barkley, Chapel Hill, NC (US)

(21) Appl. No.: 18/616,611

(22) Filed: Mar. 26, 2024

(51) Int. Cl. H01L 21/8234; H01L 21/66; H01L 23/00; H01L 25/065; H01L 25/18

(52) U.S. Cl. CPC H10D 84/038; H01L 22/12; H01L 24/94; H01L 25/0655; H01L 25/18; H10D 84/0126; H01L 24/32; H01L 24/48; H01L 24/73; H01L 2224/32225; H01L 2224/48225; H01L 2224/73265; H01L 2224/94; H01L 2924/10272; H01L 2924/12032; H01L 2924/13091

(57) ABSTRACT

Semiconductor die and methods for manufacturing the same are provided. In one example, a semiconductor wafer having a plurality of lateral semiconductor device units may be provided. One or more cut lines, which group the plurality of lateral semiconductor device units into a plurality of semiconductor die, may be determined, and the semiconductor wafer may be cut along the one or more cut lines. In some examples, semiconductor die cut from the semiconductor wafer may have the same or different sizes. In some examples, semiconductor die cut from the semiconductor wafer may have the same or different numbers of lateral semiconductor device units. In some examples, a semiconductor die cut from the semiconductor wafer may include one or more uncut scribe lines between each of a plurality of lateral semiconductor device units.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”), and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or Group III nitride-based (e.g., gallium nitride (“GaN”)) semiconductor materials.

### SUMMARY

Aspects and advantages of embodiments of the present disclosure will be set forth in part in the following description, or can be learned from the description, or can be learned through practice of the embodiments.

One example aspect of the present disclosure is directed to a method. The method includes providing a semiconductor wafer comprising a plurality of lateral semiconductor device units. The method further includes determining one or more cut lines for the semiconductor wafer. The one or more cut lines group the plurality of lateral semiconductor device units into a plurality of semiconductor die, and a first semiconductor die of the plurality of semiconductor die has a different size relative to a second semiconductor die of the plurality of semiconductor die.

Another example aspect of the present disclosure is directed to a semiconductor die. The semiconductor die includes a plurality of lateral semiconductor device units. The semiconductor die further includes one or more uncut scribe lines between each of the plurality of lateral semiconductor device units. The one or more uncut scribe lines each include a non-metal region.

Another example aspect of the present disclosure is directed to a method. The method includes providing a semiconductor wafer having a plurality of lateral semiconductor device units. The method further includes determining one or more cut lines for the semiconductor wafer. The one or more cut lines group the plurality of lateral semiconductor device units into a plurality of semiconductor die, and a first semiconductor die of the plurality semiconductor has a different number of lateral semiconductor device units relative to a second semiconductor die of the plurality of semiconductor die.

Another example aspect of the present disclosure is directed to a method. The method includes determining a unit size for a lateral semiconductor device unit. The method further includes arranging a semiconductor wafer having a plurality of lateral semiconductor device units, each of the plurality of lateral semiconductor device units having the unit size. The method further includes determining one or more dimensions for a plurality of semiconductor die, each of the plurality of semiconductor die having at least one lateral semiconductor device unit.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a top view of an example semiconductor wafer according to example embodiments of the present disclosure;

FIGS. 2A-2C depict cross-sectional views of the example semiconductor wafer of FIG. 1 according to example embodiments of the present disclosure;

FIGS. 3A-3C depict cross-sectional views of example lateral semiconductor device units according to example embodiments of the present disclosure;

FIG. 4 depicts a plan view of contact layouts of an example lateral semiconductor device unit according to example embodiments of the present disclosure;

FIG. 5 depicts a plan view of contact layouts of an example lateral semiconductor device unit according to example embodiments of the present disclosure;

FIG. 6 depicts a plan view of contact layouts of an example lateral semiconductor device unit according to example embodiments of the present disclosure;

FIGS. 7A-7F depict plan views of example semiconductor die singulated from an example semiconductor wafer according to example embodiments of the present disclosure;

FIG. 8 depicts a flow chart diagram of an example method according to example embodiments of the present disclosure;

FIG. 9 depicts a flow chart diagram of an example method according to example embodiments of the present disclosure;

FIG. 10 depicts a flow chart diagram of an example method according to example embodiments of the present disclosure;

FIG. 11 depicts an example semiconductor package of a semiconductor device according to example embodiments of the present disclosure; and

FIG. 12 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Power semiconductor device packages may include one or more semiconductor die having at least one semiconductor structure, such as a power semiconductor device. In some examples, power semiconductor devices may include a wide bandgap semiconductor material, such as silicon carbide (SiC) semiconductor materials and/or Group III nitride-based (e.g., gallium nitride (GaN)) semiconductor materials. For instance, in some examples, the one or more semiconductor die may include, e.g., wide bandgap semiconductor devices, silicon carbide-based semiconductor devices (e.g., MOSFETs, Schottky diodes), Group III nitride-based semiconductor devices (e.g., HEMT devices), and the like.

As used herein, a “wide bandgap semiconductor material” refers to a semiconductor material having a band gap greater than about 1.40 eV. Aspects of the present disclosure are discussed herein with reference to silicon carbide-based semiconductor structures/layers as wide bandgap semiconductor structures/layers for purposes of illustration and discussion. Those having ordinary skill in the art, using the disclosures provided herein, will understand that any suitable semiconductor material, such as other wide bandgap semiconductor materials, may be used without deviating from the scope of the present disclosure. By way of non-limiting example, example wide bandgap semiconductor materials include silicon carbide and/or Group III-nitrides.

In some examples, power semiconductor devices may include lateral structures (e.g., lateral semiconductor device units) and/or vertical structures (e.g., vertical semiconductor device units). In a power semiconductor device having a lateral structure, the terminals of the power semiconductor device (e.g., drain terminal, source terminal, gate terminal for a power MOSFET device) are on the same major side (e.g., top side, bottom side) of a semiconductor structure. In contrast, in a power semiconductor device having a vertical structure, at least one terminal is provided on each major side of the semiconductor structure. In other words, each terminal in a lateral semiconductor structure is coplanar, while the terminals in a vertical semiconductor structure are non-coplanar. As used herein, a “semiconductor structure” refers to a structure having one or more semiconductor layers, such as semiconductor substrates and/or semiconductor epitaxial layers.

Semiconductor devices may be fabricated by performing fabrication processes on a semiconductor wafer. A semiconductor wafer is a thin, disc-shaped sheet of semiconductor material (e.g., silicon (Si), SiC, GaN, etc.) that may serve as the foundation for manufacturing semiconductor devices, such as integrated circuits (ICs) and/or other electronic components. In some examples, semiconductor wafers may include one or more epitaxial layers formed on a substrate. As used herein, an “epitaxial layer” is a single-crystal semiconductor layer grown on top of a substrate using a process called “epitaxial growth” and/or “epitaxy.” The epitaxial layer may be deposited atom-by-atom and may adopt the crystal structure of the underlying substrate. Furthermore, a “substrate” refers to a solid semiconductor material upon which epitaxial layers are formed. A substrate may be a homogenous material, such as silicon carbide and/or sapphire and may provide mechanical support for the formation of epitaxial layers. In some examples, substrates may be provided as a semiconductor wafer on which various other layers and structures are formed. By way of non-limiting example, an example epitaxial layer may have a thickness in a range of, for instance, about 0.2 microns (μm) to about 200 microns (μm), and an example substrate may have a thickness in a range of, for instance, about 0.5 microns (μm) to about 1000 microns (μm) or greater.

A power semiconductor device (e.g., MOSFET, JFETs, Schottky diode, HEMT device, etc.) may be fabricated on a monocrystalline silicon carbide-based semiconductor wafer, which may serve as a substrate for the power semiconductor device. For instance, a plurality of “unit cell” structures (hereinafter “semiconductor device cells”) may be formed in the epitaxial layers. Each of the plurality of semiconductor device cells may include a semiconductor structure such as, for instance, a transistor or other device. In some examples, a large number (e.g., hundreds, thousands, etc.) of these semiconductor device cells may together form a semiconductor device unit, such as a lateral semiconductor device unit and/or a vertical semiconductor device unit. Metal layer structures may be formed on a side of the semiconductor structures of each of the plurality of the semiconductor device cells to form one or more electrodes for the lateral semiconductor device unit (e.g., gate contact, source contact, drain contact).

The semiconductor wafer may be subjected to wafer-level processing and singulated to form individual semiconductor die for use in a semiconductor device package, such as a discrete semiconductor device package and/or a power module. More particularly, the semiconductor wafer may include one or more scribe lines between each of the plurality of lateral semiconductor device units. The semiconductor wafer may then be cut and/or diced along the one or more scribe lines (e.g., along one or more cut lines) between the plurality of lateral semiconductor device units, such that each individual cut piece becomes a semiconductor die that is later packaged in a semiconductor device package (e.g., discrete semiconductor device package, power module).

As used herein, a “scribe line” refers to a line where the semiconductor wafer may later be cut or diced using, for instance, a wire saw and/or a laser. Hence, as used herein, an “uncut scribe line” refers to a scribe line that has not yet been cut and/or diced, and a “cut line” refers to a scribe line that has been cut and/or diced. The semiconductor wafer may include no metal, such as metal layer structures and the like, within a region defined by the one or more scribe lines. Thus, each of the one or more scribe lines may include a non-metal region. In some examples, the epitaxial layer of the semiconductor structure may have a reduced thickness in the regions defined by the one or more scribe lines (e.g., relative to the remaining epitaxial layers). In some examples, there may be no epitaxial semiconductor structure in the regions defined by the scribe lines. In some examples, only the substrate of the semiconductor wafer is in the regions defined by the scribe lines (e.g., non-metal region(s)). In this manner, the semiconductor wafer may be cut and/or diced without destroying and/or damaging the semiconductor devices on the semiconductor wafer, the cutting/dicing instrument, and the like.

During the manufacturing process, the semiconductor wafer (e.g., the plurality of lateral semiconductor device units) may undergo a series of process control and/or reliability tests to identify defects in the semiconductor wafer which may, if not identified, result in defective semiconductor die and semiconductor device packages. More particularly, semiconductor wafers and epitaxy have inherent defects that may cause one or more of the plurality of lateral semiconductor device units to be defective. Moreover, a rate of such defects (e.g., “defect density”) exponentially increases as a size of each of the plurality of lateral semiconductor devices on the semiconductor wafer is increased. Thus, each of the plurality of lateral semiconductor device units may be tested prior to cutting and/or dicing the semiconductor wafer. As used herein, the term “rejected lateral semiconductor device unit” refers to any of the plurality of lateral semiconductor device units identified as having a defect.

In semiconductor manufacturing, the defect density and location of rejected semiconductor device unit(s) greatly affects the overall efficiency and cost-effectiveness of the manufacturing process. One metric often used to quantify fabrication efficiency is “die yield” and/or “device yield.” Those having ordinary skill in the art will understand that the term “die yield” and/or “device yield” refers to the number of working (e.g., non-defective) semiconductor die on a semiconductor wafer (given as a percentage). Hence, rejected lateral semiconductor device units are one factor that may adversely affect the die yield of a corresponding semiconductor wafer.

To overcome the defect density and die yield issues discussed above, example aspects of the present disclosure are directed to semiconductor die and methods for fabricating the same. More particularly, as will be discussed in greater detail below, an example method according to the present disclosure may include providing a semiconductor wafer having a plurality of lateral semiconductor device units. In some examples, each lateral semiconductor device unit of the semiconductor wafer may include, for instance, a lateral silicon carbide-based MOSFET, a silicon carbide-based Schottky diode, and/or the like. Furthermore, each lateral semiconductor device unit may include a plurality of semiconductor device cells. As will be discussed in greater detail below, each semiconductor device cell may include one or more electrode (e.g., source contact, drain contact, gate contact) on a side of a semiconductor structure (e.g., a wide bandgap semiconductor structure).

The method may further include determining one or more cut lines for the semiconductor wafer which, as noted above, may group the plurality of lateral semiconductor device units into a plurality of semiconductor die. As will be discussed in greater detail below, the one or more cut lines may be determined based on data indicative of one or more rejected lateral semiconductor device units and/or data indicative of a defect density of the semiconductor wafer which, in turn, may increase the die yield of the semiconductor wafer. For instance, in situations where the semiconductor wafer includes one or more defects, each lateral semiconductor device unit affected by the defect may be identified, and a location of the one or more cut lines may be adjusted so as to exclude the rejected lateral semiconductor device unit(s) from being included in a fabricated semiconductor die. In other words, because each rejected lateral semiconductor device unit is unusable, example aspects of the present disclosure provide systems and methods for cutting and/or dicing the semiconductor wafer around each rejected lateral semiconductor device unit.

The method may further include cutting the semiconductor wafer into the plurality of semiconductor die along the one or more cut lines. In some examples, a laser-based cutting process may be used to cut the semiconductor wafer. Additionally and/or alternatively, in some examples, a saw-based cutting process may be used to cut the semiconductor wafer.

As will be discussed in greater detail below, to increase the die yield of the semiconductor wafer, the plurality of semiconductor die cut from the semiconductor wafer may have different sizes, different shapes, etc. For instance, in some examples, a semiconductor die (e.g., a “first” semiconductor die) of the plurality of semiconductor die may include a single lateral semiconductor device unit (e.g., lateral silicon carbide-based MOSFET, silicon carbide-based Schottky diode, etc.). Another example semiconductor die (e.g., a “second” semiconductor die) of the plurality of semiconductor die may include a plurality of lateral semiconductor device units arranged on the semiconductor die and one or more uncut scribe lines between each of the plurality of lateral semiconductor device units; each of the one or more uncut scribe lines includes a non-metal region.

A unit size for each of the plurality of lateral semiconductor device units may be determined based on, inter alia, post-fabrication plan data associated with a plurality of reference semiconductor die. In some examples, the post-fabrication plan data may include dimensional measurements for each of the plurality of reference semiconductor die from a reference semiconductor wafer. For instance, in some examples, the unit size for the plurality of lateral semiconductor device units may be substantially similar to a unit size of a smallest reference semiconductor die of the plurality of reference semiconductor die. In addition to the dimensional measurements for each of the plurality of reference semiconductor die, the post-fabrication plan data may also include, for instance, a die yield of the reference semiconductor die. For instance, in some examples, the post-fabrication plan data may include data indicative of a defect density of the reference semiconductor wafer. In this way, the unit size of each of the plurality of lateral semiconductor device units may increase the die yield for the semiconductor wafer.

In some examples, one or more dimensions for the plurality of semiconductor die may also be determined based on data associated with the plurality of reference semiconductor die. By determining one or more dimensions for each of the plurality of semiconductor die based on the one or more rejected lateral semiconductor die units and/or the plurality of reference semiconductor die, the die yield of the semiconductor wafer may be increased. Furthermore, one or more of the plurality of semiconductor die may be cut and/or diced in a manner that increases the die yield of the semiconductor wafer while, at the same time, reducing waste.

For instance, a first semiconductor die of the plurality of semiconductor die may have a different size (e.g., different surface area) than a second semiconductor die of the plurality of semiconductor die. Additionally and/or alternatively, in some examples, one or more of the plurality of semiconductor die may have a different number of lateral semiconductor device units. For instance, a first semiconductor die of the plurality of semiconductor die may be fabricated so as to include a different number of lateral semiconductor device units relative to a second semiconductor die of the plurality of semiconductor die. As such, a semiconductor die according to the present disclosure may include a plurality of lateral semiconductor device units and one or more uncut scribe lines between each of the plurality of lateral semiconductor device units.

Example aspects of the present disclosure provide a number of technical effects and benefits. For instance, by determining a unit size for a plurality of lateral semiconductor device units based on a plurality of reference semiconductor die from reference semiconductor wafers, a defect density of example semiconductor wafers of the present disclosure may be reduced. Moreover, a die yield of the example semiconductor wafers may be increased by the example fabrication methods disclosed herein. For instance, one or more dimensions for each of a plurality of semiconductor die may be individually determined based on a defect density of the example semiconductor wafers which, in turn, provides for increased design flexibility during the fabrication process. By singulating semiconductor die based on the semiconductor wafer quality (e.g., defect density), semiconductor die having different sizes and/or numbers of lateral semiconductor device units may be cut and/or diced from the semiconductor wafer. In this manner (e.g., by singulating around rejected lateral semiconductor device units), semiconductor wafer waste may be reduced, while the die yield of the singulated semiconductor wafer may be increased.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

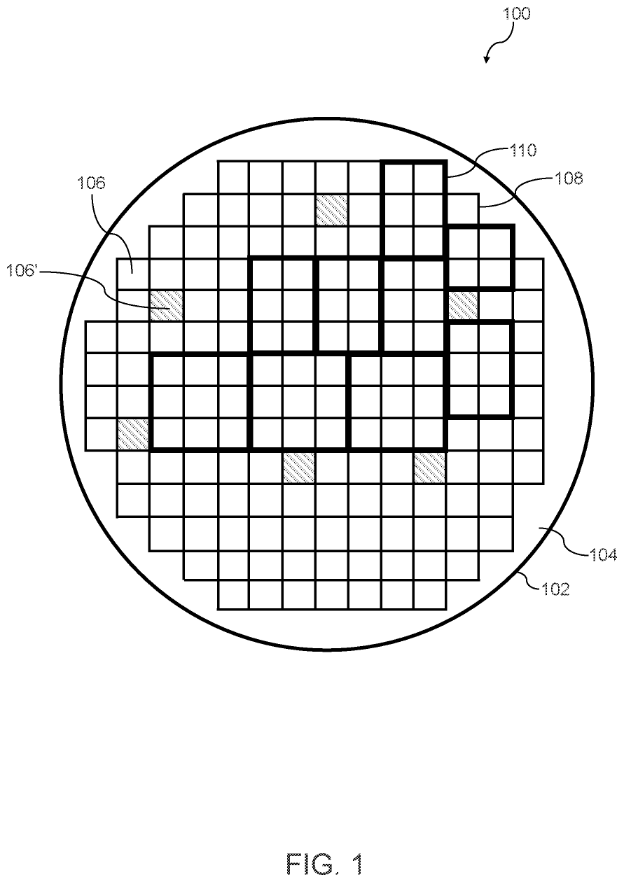

FIG. 1 depicts a top view of an example semiconductor wafer 100 according to example embodiments of the present disclosure. As noted above, the semiconductor wafer 100 may serve as the foundation for manufacturing semiconductor devices, such as integrated circuits (ICs) and/or other electronic components. It should be understood that FIG. 1 is intended to represent structures for purposes of identification and description and is not intended to represent the structures to physical scale.

The semiconductor wafer 100 may be a thin, disc-shaped sheet of semiconductor material, such as silicon (Si), silicon carbide (SiC), gallium nitride (GaN), and the like. More particularly, the semiconductor wafer 100 may include a substrate 102. As will be discussed in greater detail below, in some examples, the semiconductor wafer 100 may include one or more epitaxial layers 104, which may be a single-crystal semiconductor layer grown on a top side of the substrate 102.

The substrate 102 may include a semiconductor material. By way of non-limiting example, the substrate 102 may be a silicon substrate, a silicon-carbide substrate, a sapphire substrate, and/or other suitable substrates. In some examples, the substrate 102 may be a SiC substrate that may include, for example, the 4H polytype of SiC or may be the 3C, 6H, and 15R polytypes of SiC.

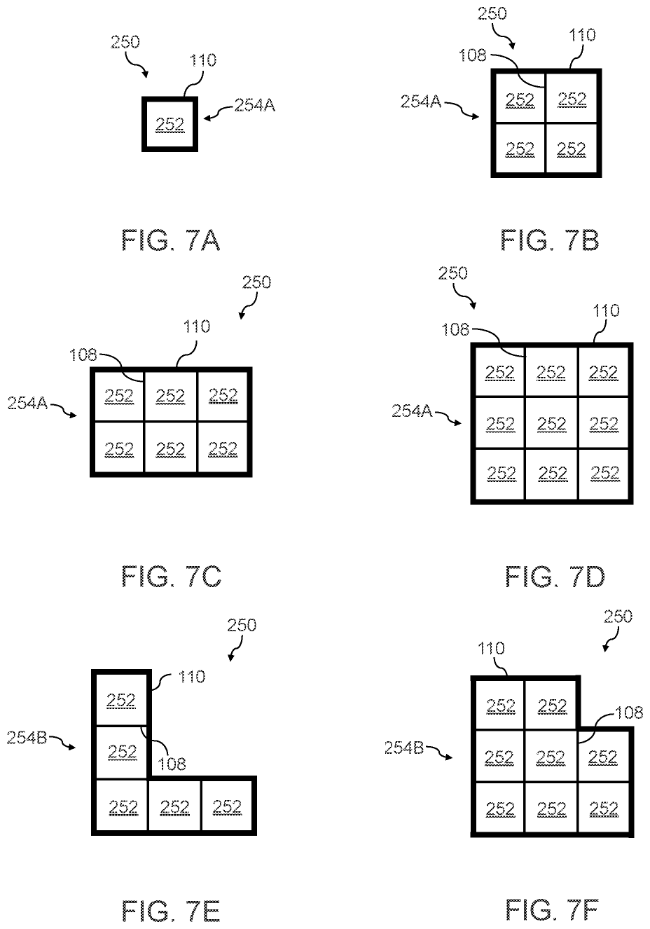

The semiconductor wafer 100 may include a plurality of lateral semiconductor device units 106. Each lateral semiconductor device unit 106 may include, for instance, a lateral silicon carbide-based MOSFET, a silicon carbide-based Schottky diode, and/or the like. As will be discussed in greater detail below (e.g., FIGS. 7A-7F), each of the plurality of lateral semiconductor device units 106 may have an associated blocking voltage. As used herein, the term “blocking voltage” refers to the maximum reverse voltage (e.g., reverse bias voltage) the lateral semiconductor device unit can withstand before experiencing a phenomenon known as “avalanche breakdown” where an increasing electric field results in a runaway generation of charge carriers within the lateral semiconductor device unit, resulting in a sharp increase in current that may damage or even destroy the device.

As noted above, during fabrication, the semiconductor wafer 100 may undergo a series of process control and/or reliability tests to identify defects in the semiconductor wafer 100, such as defects in the plurality of lateral semiconductor device units 106. For instance, one or more of the plurality of lateral semiconductor device units 106 may be defective due to anomalies in the manufacturing process, and a rate of such defects (e.g., defect density) exponentially increases as a size of the lateral semiconductor device units 106 on the semiconductor wafer 100 is increased. It should be understood that lateral semiconductor device units 106 having identified defects are referred to and depicted herein as rejected lateral semiconductor device units 106′.

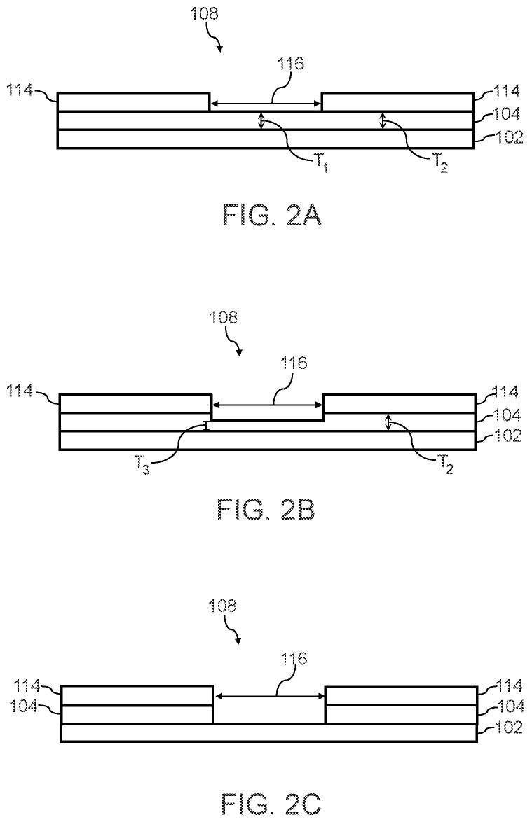

The semiconductor wafer 100 may further include one or more scribe lines 108 between each of the plurality of lateral semiconductor device units 106. As noted above, the one or more scribe lines 108 define where the semiconductor wafer 100 may later be cut and/or diced using, for instance, a wire saw, a laser, and/or the like. The semiconductor wafer 100 may further include one or more cut lines 110, which correspond to a scribe line 108 that has been cut and/or diced. The semiconductor wafer 100 may include no metal, such as metal layer structures and the like, within a region defined by the one or more scribe lines 108 and the one or more cut lines 110. Hence, the one or more scribe lines 108 and/or the one or more cut lines 110 may include, and likewise define, a non-metal region 116 (FIGS. 2A-2C) of the semiconductor wafer 100. Furthermore, as will be discussed in greater detail below, the one or more cut lines 110 may group the plurality of lateral semiconductor device units 106 into a plurality of semiconductor die 112.

Referring briefly to FIGS. 2A-2C, cross-sectional views of the example semiconductor wafer 100 are depicted according to example embodiments of the present disclosure. FIGS. 2A-2C depict a portion of the example semiconductor wafer 100 and are intended to represent structures for purposes of identification and discussion. However, FIGS. 2A-2C are not intended to represent the structures of the example semiconductor wafer 100 to physical scale.

As shown in FIGS. 2A-2C, the epitaxial layer 104 may be formed on the substrate 102 of the semiconductor wafer 100, and the one or more scribe lines 108 may be between adjacent metallization structures 114 of the plurality of lateral semiconductor device units 106 (not shown). Put differently, the semiconductor wafer 100 include no metal, such as the metallization structures 114, in the non-metal region 116 defined by the uncut scribe line 108.

In some examples (e.g., FIG. 2A), the epitaxial layer 104 may have a thickness T₁ in the non-metal region 116 that is substantially similar to a thickness T₂ outside of the non-metal region 116. In other examples (e.g., FIG. 2B), the epitaxial layer 104 may have a reduced thickness T₃ in the non-metal region 116 relative to the thickness T₂ outside of the non-metal region 116. In other examples (e.g., FIG. 2C), the epitaxial layer 104 may be etched or otherwise removed from the non-metal region 116 such that no epitaxial layer structure remains (e.g., leaving only the substrate 102) in the non-metal region 116.

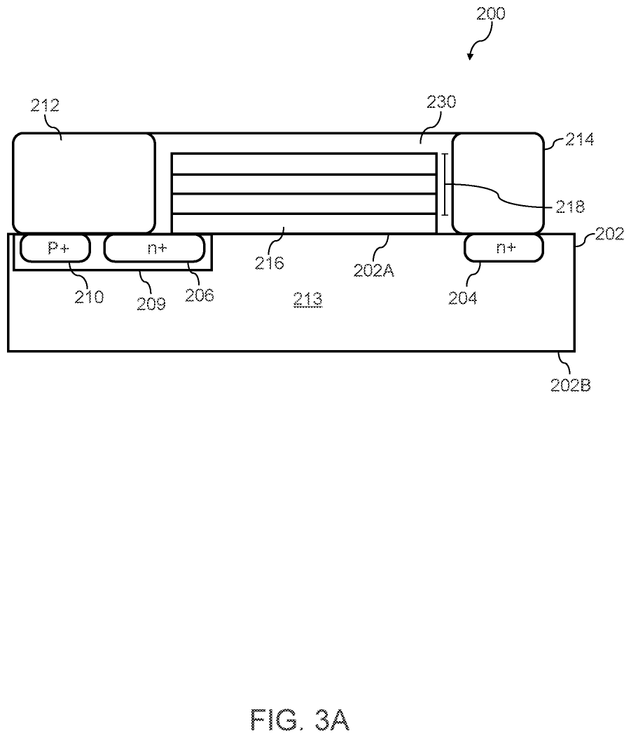

FIGS. 3A-3C depict cross-sectional views of an example semiconductor device cell 200 of the plurality of semiconductor device cells in example lateral semiconductor device units according to example embodiments of the present disclosure. The semiconductor device cell 200 may be included in any of the lateral semiconductor device units described herein, such as any of the plurality of lateral semiconductor device units 106 on the semiconductor wafer 100 described herein with reference to FIG. 1. It should be understood that FIGS. 3A-3C are intended to represent structures for purposes of identification and description and is not intended to represent the structures to physical scale.

Referring now to FIG. 3A, a cross-section of an example semiconductor device cell 200 is depicted. The semiconductor device cell 200 may be one of a plurality of semiconductor device cells in an example lateral semiconductor device unit. In some examples, such as that depicted in FIG. 3A, the lateral semiconductor device unit may be a high voltage MOSFET. However, it should be understood that FIG. 3A depicts a high voltage MOSFET for purposes of illustration and discussion. The lateral semiconductor device unit may be any suitable lateral semiconductor device unit without deviating from the scope of the present disclosure.

The semiconductor device cell 200 may include a wide bandgap semiconductor structure, such as an epitaxial layer 202 (e.g., epitaxial silicon carbide layer). The epitaxial layer 202 may include a first side 202A and an opposing second side 202B. It should be understood that the epitaxial layer 202 depicted in FIG. 3A may be similar to any of the epitaxial layers described herein, such as the epitaxial layer 104 of the semiconductor wafer 100 described herein with reference to FIGS. 1-2C. The epitaxial layer 202 may have a thickness in a range of about 0.2 microns (μm) to about 200 microns (μm), such as about 0.5 microns (μm) to about 100 microns (μm), such as about 0.5 microns (μm) to about 20 microns (μm).

As shown, the semiconductor device cell 200 may include a source contact 212, a drain contact 214, and a gate contact 218 on the first side 202A of the epitaxial layer 202. Thus, the semiconductor device cell 200 is a lateral device. As noted above, in some examples, the epitaxial layer 202 may be formed on a top side of a substrate, such as the substrate 102 (FIGS. 1-2C). In such examples, the second side 202B of the epitaxial layer 202 may contact the substrate (not shown). Additionally and/or alternatively, in some examples, the second side 202B of the epitaxial layer 202 may be free from contact with a substrate, such as the substrate 102 (FIGS. 1-2C). In some examples, the epitaxial layer 202 may be on a silicon substrate (not shown). In some examples, the epitaxial layer 202 may be on a silicon carbide substrate (not shown). In some examples, the epitaxial layer 202 may be on a sapphire substrate (not shown). In some examples, there is no semiconductor substrate.

In some examples, such as that depicted in FIG. 3A, the semiconductor device cell 200 may be a MOSFET, such as a lateral silicon carbide-based MOSFET. For instance, as noted above, the semiconductor device cell 200 may be an n-type high voltage MOSFET. More particularly, the epitaxial layer 202 may include a drift region 213 having a first conductivity type (e.g., n-type). Hence, the drift region 213 may be an “n− region.” At least a portion of the drift region 213 may be in the epitaxial layer 202 between the source contact 212 and the drain contact 214.

An upper portion of the epitaxial layer 202 (e.g., upper portion of the drift region 213) may be doped by ion implantation to form a p-well 209 having a second conductivity type (e.g., p-type). Hence, the p-well 209 may be a “p+ region.” An upper portion of the p-well 209 may be more heavily doped with dopants of the second conductivity type (e.g., p-type) to form a more-heavily doped well region 210 having the second conductivity type (e.g., p-type). Hence, the well region 210 may likewise be a “p+ region.” The well region 210 may be in the epitaxial layer 202 between the drift region 213 and the source contact 212. The p-well 209 and the well region 210 may be formed by ion implantation. Ions, such as n-type or p-type dopants, may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer to a certain depth.

The epitaxial layer 202 may further include a source region 206 having the first conductivity type (e.g., n-type). Hence, the source region 206 may be an “n+ region.” The source region 206 may be in the epitaxial layer 202 proximate to the source contact 212. In some examples, the source region 206 may be formed in an upper portion of the p-well 209 directly adjacent the well region 210. Like the p-well 209 and the well region 210, the source region 206 may also be formed by ion implantation. The epitaxial layer 202 may further include a drain region 204 having the first conductivity type (e.g., n-type). Hence, the drain region 204 may be an “n+ region.” The drain region 204 may be in the epitaxial layer 202 proximate to the drain contact 214.

In some examples, the source contact 212 and the drain contact 214 are each ohmic contacts with the epitaxial layer 202. For instance, by way of non-limiting example, the source contact 212 and the drain contact 214 may each include a nickel-based conductive layer, such as nickel (Ni) and/or nickel-silicide (NiSi). It should be understood that other suitable metals capable of making an ohmic contact with the epitaxial layer 202 may be used without deviating from the scope of the present disclosure.

In some examples, the gate contact 218 may be on the first side 202A of the epitaxial layer 202. The gate contact 218 may be, for instance, a multilayer gate contact 218. In such examples, the gate contact 218 may include, for instance, one or more polysilicon layers, one or more metal layers, one or more intermetal dielectric (IMD) layers, and the like. The semiconductor device cell 200 may include a gate dielectric 216 between the gate contact 218 and the epitaxial layer 202. The gate dielectric 216 may be, for instance, an oxide, such as silicon dioxide (SiO₂). Due to the conductive nature of the p-well 209, an electric field of the gate dielectric 216 may invert to the first conductivity type (e.g., n-type), thereby forming a channel, when a voltage is applied to the gate contact 218. Current may flow from the source region 206 through the channel to the portion of the drift region 213 that is underneath the gate contact 218.

Referring still to FIG. 3A, an underfill material 230 may be between the source contact 212 and the drain contact 214. The underfill material 230 may be, for instance, a composite material made from a polymer (e.g., epoxy polymer) with filler and/or additional components. The underfill material 230 may provide creepage between the source contact 212 and the drain contact 214. Put differently, the underfill material 230 may act as an insulating material between the source contact 212 and the drain contact 214 to prevent leakage and/or breakdown between the source contact 212 and the drain contact 214.

It should be understood that, in the above description of FIG. 3A, it is assumed that the semiconductor device cell 200 is an n-type power MOSFET. However, those having ordinary skill in the art, using the disclosures provided herein, will understand that aspects of the present disclosure may be implemented in any suitable semiconductor device (e.g., p-type power MOSFETs, Schottky diodes, BJTs, IGBTs, GTOs, JFETs, HEMTs, etc.) without deviating from the scope of the present disclosure.

For instance, referring now to FIG. 3B, another cross-section of the example semiconductor device cell 200 is depicted. Like the semiconductor device cell 200 depicted in FIG. 3A, the semiconductor device cell 200 depicted in FIG. 3B may be one of a plurality of semiconductor device cells in an example lateral semiconductor device unit. In contrast to FIG. 3A, however, the semiconductor device cell 200 of FIG. 3B may be a low voltage MOSFET. The semiconductor device cell of FIG. 3B is depicted as a low voltage MOSFET for purposes of illustration and discussion, and the lateral semiconductor device unit may be any suitable lateral semiconductor device unit without deviating from the scope of the present disclosure.

The semiconductor device cell 200 depicted in FIG. 3B may include similar structures and/or regions to the semiconductor device cell 200 discussed above with reference to FIG. 3A. For instance, as shown, the semiconductor device cell 200 may include a wide bandgap semiconductor structure, such as the epitaxial layer 202 discussed above. The semiconductor device cell 200 may also include the source contact 212, the drain contact 214, and the gate contact 218 on the first side 202A of the epitaxial layer 202. Thus, the semiconductor device cell 200 depicted in FIG. 3B is a lateral device. Furthermore, the semiconductor device cell 200 of FIG. 3B may include the underfill material 230, which may act as an insulating material, between the source contact 212 and the drain contact 214.

Like the semiconductor device cell 200 depicted in FIG. 3A, the epitaxial layer 202 of the semiconductor device cell 200 depicted in FIG. 3B may have the first conductivity type (e.g., n-type), and at least a portion of the drift region 213 may be in the epitaxial layer 202 between the source contact 212 and the drain contact 214. An upper portion of the epitaxial layer 202 (e.g., upper portion of the drift region 213) may also be doped by ion implantation to form the p-well 209 having the second conductivity type (e.g., p-type). The epitaxial layer 202 may further include the source region 206 having the first conductivity type (e.g., n-type), which may be formed proximate to the source contact 212.

However, in contrast to the p-well 209 of the semiconductor device cell 200 depicted in FIG. 3A, the p-well 209 of the semiconductor device cell 200 depicted in FIG. 3B does not include a more-heavily doped well region 210 (FIG. 3A). Moreover, while the semiconductor device cell 200 of FIG. 3B does include the drain region 204, the drain region 204 having the first conductivity type (e.g., n-type), may be formed in the p-well 209 itself. As shown, the drain region 204 may be in the p-well 209 proximate to the drain contact 214. In this manner, the semiconductor device cell 200 depicted in FIG. 3B may be a low voltage n-type power MOSFET.

As discussed above, the semiconductor device cells 200 depicted in FIGS. 3A-3B may include the epitaxial layer 202 having the first conductivity type (e.g., n-type). However, semiconductor device cells according to the present disclosure may include an epitaxial layer may include any suitable conductivity type.

For instance, referring now to FIG. 3C, another cross-section of the example semiconductor device cell 200 is depicted. Like the semiconductor device cells 200 depicted in FIGS. 3A-3B, the semiconductor device cell 200 depicted in FIG. 3C may be one of a plurality of semiconductor device cells in an example lateral semiconductor device unit. Additionally, like the semiconductor device cell 200 of FIG. 3B, the semiconductor device cell 200 of FIG. 3C may also be a low voltage MOSFET. The semiconductor device cell of FIG. 3C is depicted as a low voltage MOSFET for purposes of illustration and discussion, and the lateral semiconductor device unit may be any suitable lateral semiconductor device unit without deviating from the scope of the present disclosure.

The semiconductor device cell 200 depicted in FIG. 3C may include similar structures and/or regions to the semiconductor device cell 200 discussed above with reference to FIGS. 3A-3B. For instance, as shown, the semiconductor device cell 200 may include the source contact 212, the drain contact 214, and the gate contact 218 on the first side 202A of the epitaxial layer 202. Thus, the semiconductor device cell 200 depicted in FIG. 3C is a lateral device. Furthermore, the semiconductor device cell 200 of FIG. 3C may include the underfill material 230, which may act as an insulating material, between the source contact 212 and the drain contact 214.

The semiconductor device cell 200 of FIG. 3C also includes a wide bandgap semiconductor structure, such as the epitaxial layer 202 discussed above. However, in contrast to the semiconductor device cell 200 of FIG. 3B, the epitaxial layer 202 of the semiconductor device cell 200 of FIG. 3C includes a drift region 225 having the second conductivity type (e.g., p-type). Hence, the drift region 225 may be a “p+ region.” At least a portion of the drift region 225 may be in the epitaxial layer 202 between the source contact 212 and the drain contact 214.

Due to the conductive nature of the drift region 225, the semiconductor device cell 200 of FIG. 3C does not include a p-well 209 (FIGS. 3A-3B) and/or a more-heavily doped well region 210 (FIG. 3A). Rather, the epitaxial layer 202 may include the source region 206 and the drain region 204, both of which having the first conductivity type (e.g., n-type), in the drift region 213 itself. As shown, the source region 206 may be proximate to the source contact 212 in the drift region 213, and the drain region 204 may be proximate to the drain contact 214 in the drift region 213. In this manner, the semiconductor device cell 200 depicted in FIG. 3C may be a low voltage p-type power MOSFET.

FIGS. 3A-3C depict example lateral semiconductor device units and example semiconductor device cells for purposes of illustration and discussion. Thos having ordinary skill in the art, using the disclosures provided herein, will understand that different semiconductor device unit configurations and different semiconductor device cell configurations may be used without deviating from the scope of the present disclosure.

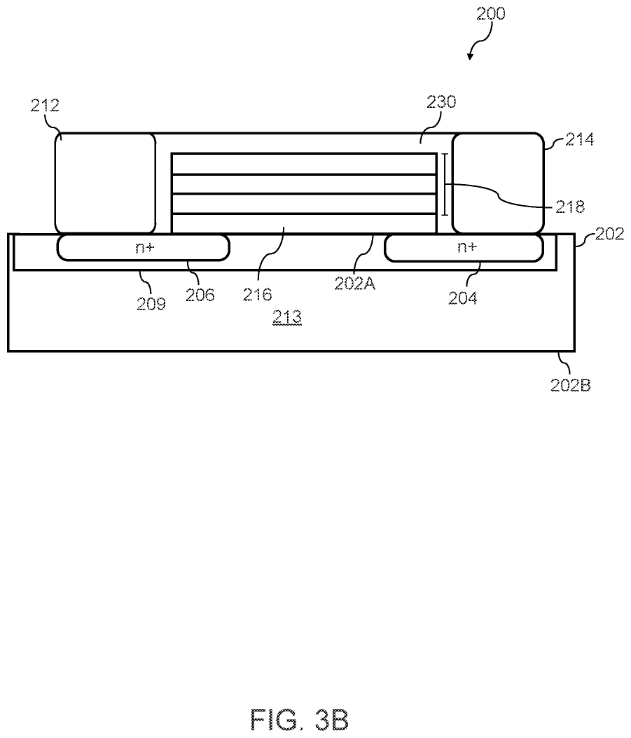

Due to the lateral nature of the semiconductor device cell 200, the source contact 212, the drain contact 214, and the gate contact 218 may be provided in various patterns on the first side 202A of the epitaxial layer 202. By way of non-limiting illustrative example, FIGS. 4-6 depict plan views of example contact patterns on the first side 202A of the epitaxial layer 202 according to example embodiments of the present disclosure. It should be understood that FIGS. 4-6 are intended to represent structures for purposes of identification and description and are not intended to represent the structures to physical scale.

For instance, FIG. 4 depicts an example source contact 212, drain contact 214, and gate contact 218 on the first side 202A of the epitaxial layer 202. A gate pad 220 may be an electrical connection to the gate contact 218. The gate contact 218 may be between the source contact 212 and the drain contact 214. The source contact 212 and the drain contact 214 may be interdigitated with one another. For instance, each of the source contact 212 and the drain contact 214 may have a comb-like pattern. Fingers of the comb-like pattern of the source contact 212 are interdigitated with fingers of the comb-like pattern of the drain contact 214.

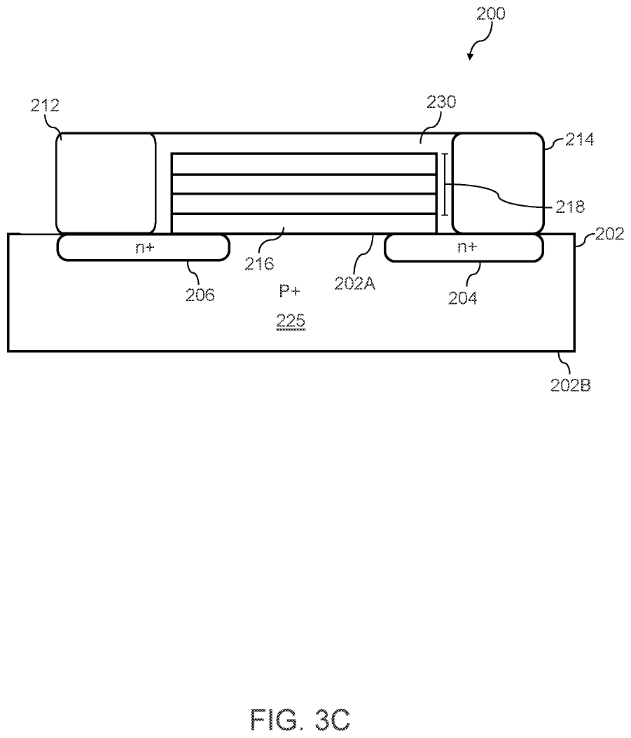

Additionally and/or alternatively, FIG. 5 depicts an example source contact 212, drain contact 214, and gate contact 218 on the first side 202A of the epitaxial layer 202. A gate pad 220 may be an electrical connection to the gate contact 218. The gate contact 218 may be between the source contact 212 and the drain contact 214. Similar to FIG. 4, the source contact 212 and the drain contact 214 are interdigitated with one another. For instance, each of the source contact 212 and the drain contact 214 have a comb-like pattern. Fingers of the comb-like pattern of the source contact 212 are triangular in shape. Fingers of the comb-like pattern of the drain contact 214 are triangular in shape. Fingers of the comb-like pattern of the source contact 212 are interdigitated with fingers of the comb-like pattern of the drain contact 214.

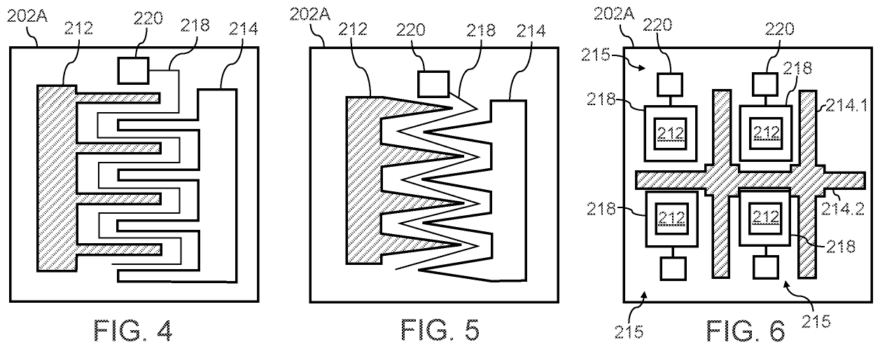

Additionally and/or alternatively, FIG. 6 depicts an example source contact 212, drain contact 214, and gate contact 218 on the first side 202A of the epitaxial layer 202. The drain contacts 214 may include a plurality of intersecting drain buses 214.1, 214.2, . . . 214.N, which together form a grid pattern. The source contact 212 may include a plurality of source contacts 212 that may be located within spaces 215 formed in the grid pattern. The gate contact 218 may include a plurality of gate contacts 218 with gate pads 220 providing electrical connections for the gate contacts 218. Each gate contact 218 at least partially surrounds one of the plurality of source contacts 212 in a space 215 formed by the drain contacts 214.

It should be understood that FIGS. 4-6 depict example layouts and patterns of source contacts 212, drain contacts 214, and gate contacts 218 for purposes of illustration and discussion. Those having ordinary skill in the art, using the disclosures provided herein, will understand that aspects of the present disclosure may use other contact patterns and layouts without deviating from the scope of the present disclosure.

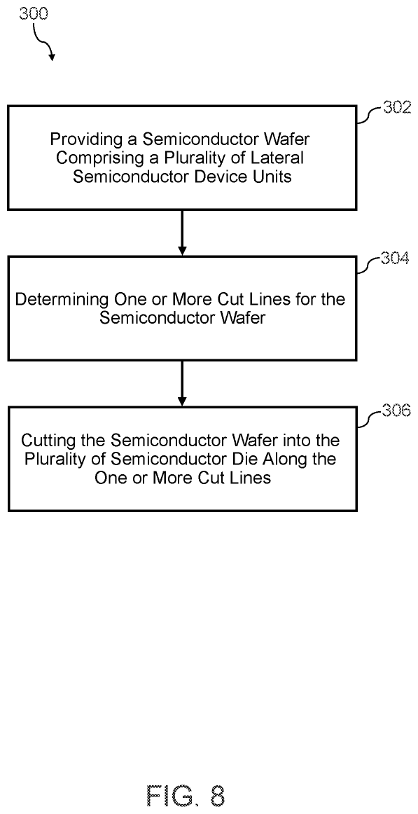

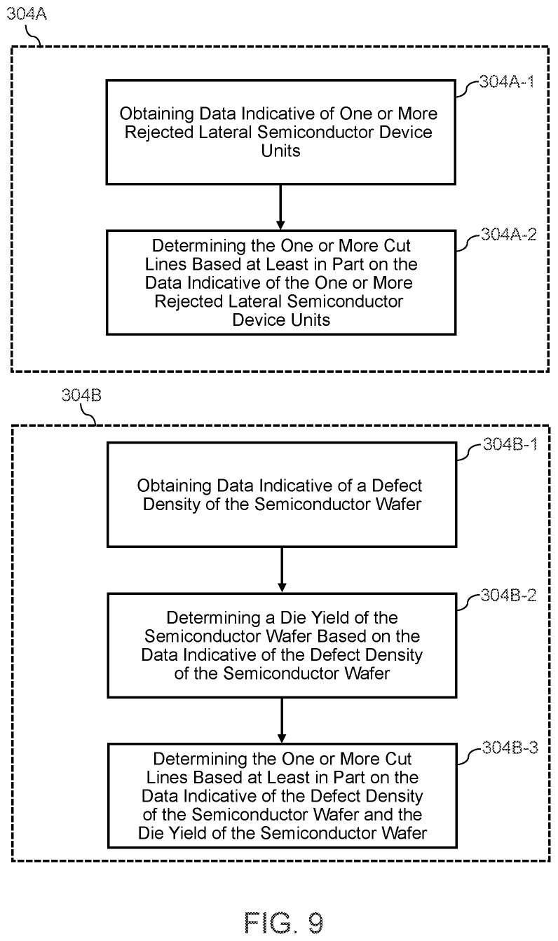

As discussed herein, example aspects of the present disclosure are directed to semiconductor die and methods for fabricating the same. More particularly, as will be discussed in greater detail below (e.g., FIGS. 8-9), a semiconductor wafer (e.g., semiconductor wafer 100 (FIG. 1)) having a plurality of lateral semiconductor device units (e.g., with a plurality of semiconductor device cells 200 (FIGS. 3-6)) may be singulated (e.g., cut, diced, etc.) into a plurality of semiconductor die along one or more cut lines (e.g., cut lines 110 (FIG. 1)).

By way of non-limiting illustrative example, FIGS. 7A-7F depict plan views of example semiconductor die 250 according to example embodiments of the present disclosure. In some examples, the semiconductor die 250 depicted in FIGS. 7A-7F may be singulated from a semiconductor wafer, such as the semiconductor wafer 100 discussed above with reference to FIG. 1. Hence, the semiconductor die 250 may correspond to the plurality of semiconductor die 112 discussed above with reference to FIG. 1. It should be understood that FIGS. 7A-7F are intended to represent structures for purposes of identification and description and are not intended to represent the structures to physical scale.

As shown in FIGS. 7A-7F, each semiconductor die 250 may include at least one semiconductor device unit 252. It should be understood that the semiconductor device units 252 depicted in FIGS. 7A-7F may be similar to any of the semiconductor device units described herein, such as the plurality of lateral semiconductor device units 106 (FIG. 1). The semiconductor device units 252 may include a plurality of semiconductor device cells, such as a plurality of the semiconductor device cells 200 (FIGS. 3-6). Furthermore, the example semiconductor wafer (not shown) may be cut and/or diced into a plurality of semiconductor die 250 along the one or more cut lines 110. In other words, as shown, the one or more cut lines 110 may group the at least one semiconductor device unit 252 into the plurality of semiconductor die 250.

As discussed in greater detail below, in some examples, the semiconductor wafer may be cut and/or diced such that the singulated semiconductor die 250 have different sizes, shapes, layouts, etc. For instance, in some examples, the semiconductor die 250 may have a rectangular shape (e.g., FIGS. 7A-7D), and, in other examples, the semiconductor die 250 may have a non-rectangular shape (e.g., FIGS. 7E-7F). Moreover, in some examples, the semiconductor die 250 may include a single lateral semiconductor device unit 252 (e.g., FIG. 7A). In some examples, the semiconductor die 250 may include two or more lateral semiconductor device units 252 (e.g., FIGS. 7B-7F). In such examples, as shown, the semiconductor die 250 may include one or more uncut scribe lines 108, each of which having a non-metal region, between each of the plurality of lateral semiconductor device units 252.

In some examples (e.g., FIGS. 7B-7D), a plurality of the lateral semiconductor device units 252 may be arranged in a rectangular array 254A on the semiconductor die 250. For instance, as shown in FIG. 7B, at least four lateral semiconductor device units 252 may be arranged in the rectangular array 254A on the semiconductor die 250. Additionally and/or alternatively, as shown in FIG. 7C, at least six lateral semiconductor device units 252 may be arranged in the rectangular array 254A on the semiconductor die 250. Additionally and/or alternatively, as shown in FIG. 7D, at least nine lateral semiconductor device units 252 may be arranged in the rectangular array 254A on the semiconductor die 250. It should be understood that any suitable number of lateral semiconductor device units 252 may be arranged in the rectangular array 254A on the semiconductor die 250 without deviating from the scope of the present disclosure.

In some examples (e.g., FIGS. 7E-7F), a plurality of lateral semiconductor device units 252 may be arranged in a non-rectangular array 254B on the semiconductor die 250. For instance, as shown in FIG. 7E, at least five lateral semiconductor device units 252 may be arranged in the non-rectangular array 254B on the semiconductor die 250. Additionally and/or alternatively, as shown in FIG. 7F, at least eight lateral semiconductor device units 252 may be arranged in the non-rectangular array 254B on the semiconductor die 250. It should be understood that any suitable number of lateral semiconductor device units 252 may be arranged in the non-rectangular array 254B on the semiconductor die 250 without deviating from the scope of the present disclosure.

It should be understood that FIGS. 7A-7F depict example sizes, shapes, layouts, dimensions, etc. of singulated semiconductor die 250 for purposes of illustration and discussion. Those having ordinary skill in the art, using the disclosures provided herein, will understand that aspects of the present disclosure may singulate semiconductor die having different sizes, shapes, layouts, dimensions, etc. without deviating from the scope of the present disclosure.

FIGS. 8-9 depict flow charts of an example method 300 according to example embodiments of the present disclosure. FIGS. 8-9 depict example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

Referring to FIG. 8, at (302), the method 300 includes providing a semiconductor wafer having a plurality of lateral semiconductor device units. The semiconductor wafer may be similar to any of the semiconductor wafers described herein (e.g., semiconductor wafer 100). Similarly, the semiconductor wafer may include any of the lateral semiconductor device units described herein (e.g., lateral semiconductor device units 106). For instance, in some examples, each lateral semiconductor device unit may include a lateral silicon carbide-based MOSFET, a silicon carbide-based Schottky diode, and the like. Furthermore, each lateral semiconductor device unit may include a plurality of semiconductor device cells. Each semiconductor device cell may include, for instance, a source contact, a drain contact, and a gate contact arranged on a first side of a semiconductor structure, such as a wide bandgap semiconductor structure (e.g., silicon carbide structure, Group III-nitride structure, etc.). For instance, in some examples (FIGS. 4-5), the drain contact may be at least partially interdigitated with the source contact. In some examples (FIG. 6), the gate contact may at least partially surround the source contact.

Referring to FIG. 8, at (304), the method 300 includes determining one or more cut lines for the semiconductor wafer. The one or more cut lines may define one or more non-metal regions of the semiconductor wafer (e.g., provided at (302)) and may group the plurality of lateral semiconductor device units into a plurality of semiconductor die.

As an illustrative example, FIG. 9 depicts example methods for determining the one or more cut lines for the semiconductor wafer at (304) (FIG. 8) according to example embodiments of the present disclosure. In some examples, to determine the one or more cut lines for the semiconductor wafer at (304A), the method 300 may include obtaining data indicative of one or more rejected lateral semiconductor device units at (304A-1) and determining the one or more cut lines based at least in part on the data indicative of the one or more rejected lateral semiconductor device units at (304A-2). Additionally and/or alternatively, to determine the one or more cut lines for the semiconductor wafer at (304B), the method 300 may include obtaining data indicative of a defect density of the semiconductor wafer at (304B-1) and determining a die yield of the semiconductor wafer based on the data indicative of the defect density of the semiconductor wafer at (304B-2). The one or more cut lines may then be determined, at (304B-3), based on the data indicative of the defect density of the semiconductor wafer and the die yield of the semiconductor wafer.

For instance, by way of non-limiting example, each rejected lateral semiconductor device unit 106′ on the semiconductor wafer 100 (FIG. 1) may be identified, and the one or more cut lines 110 may be determined based on the rejected lateral semiconductor device units 106′. A defect density and a die yield of the semiconductor wafer 100 may also be determined based on the rejected lateral semiconductor device units 106′, and the one or more cut lines 110 may be determined based on the determined defect density and die yield of the semiconductor wafer 100.

Referring again to FIG. 8, at (306), the method 300 includes cutting the semiconductor wafer into the plurality of semiconductor die along the one or more cut lines. The semiconductor wafer may be cut using, for instance, a laser-based cutting process and/or a saw-based cutting process. By way of non-limiting example, the semiconductor wafer 100 (FIG. 1) may be cut into a plurality of semiconductor die 250 (FIGS. 7A-7F) along the one or more cut lines 110.

In some examples, a first semiconductor die of the plurality of semiconductor die may have a different size relative to a second semiconductor die of the plurality of semiconductor die. Additionally and/or alternatively, in some examples, a first semiconductor die of the plurality of semiconductor die may have a different number of lateral semiconductor device units relative to a second semiconductor die of the plurality of semiconductor die. For instance, in some examples, the first semiconductor die may include a single lateral semiconductor device unit (FIG. 7A), and the second semiconductor die may include two or more lateral semiconductor device units (FIGS. 7B-7F). In some examples, the first semiconductor die may include two or more semiconductor device units and the second semiconductor die may also include two or more semiconductor device units, but the first semiconductor die may include a different number of semiconductor device units relative to the second semiconductor die.

In some examples, a first semiconductor die of the plurality of semiconductor die may have a different shape relative to a second semiconductor die of the plurality of semiconductor die. For instance, in some examples, the first semiconductor die may have a rectangular shape with a plurality of lateral semiconductor die arranged in a rectangular array thereon (e.g., FIGS. 7A-7D), and the second semiconductor die may have a non-rectangular shape with a plurality of lateral semiconductor die arranged in a non-rectangular array thereon (e.g., FIGS. 7E-7F). In some examples, the first semiconductor die and the second semiconductor die may both have a rectangular shape, but the first semiconductor die and the second semiconductor die may different numbers of lateral semiconductor device units arranged in rectangular arrays thereon.

Furthermore, as noted above, each of the plurality of lateral semiconductor device units may be associated with a blocking voltage. After the semiconductor wafer is cut into the plurality of semiconductor die, a blocking voltage associated with the first semiconductor die may be substantially the same as a blocking voltage associated with the second semiconductor die. However, an on-resistance associated with the first semiconductor die may be different from an on-resistance associated with the second semiconductor die. As used herein, the term “on-resistance” refers to the resistance between a drain electrode (e.g., drain contact 214) and source electrode (e.g., source contact 212) during operation of the semiconductor device (e.g., semiconductor device calls 200).

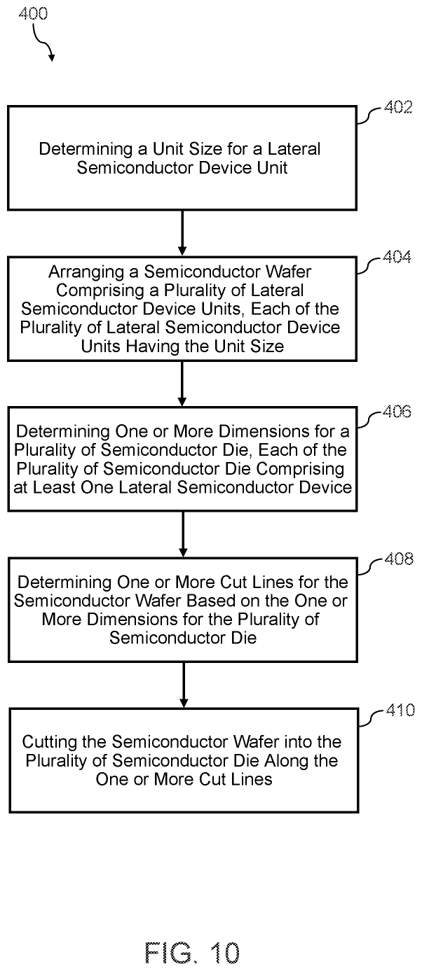

FIG. 10 depicts a flow chart of an example method 400 according to example embodiments of the present disclosure. FIG. 10 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At (402), the method 400 includes determining a unit size for a lateral semiconductor device unit. As used herein, the term “unit size” corresponds to the size, shape, and/or dimensions of a semiconductor structure, such as the lateral semiconductor device unit. To determine the unit size for the lateral semiconductor device unit, the method 400 may include obtaining post-fabrication plan data associated with a plurality of reference semiconductor wafers and, then, determining the unit size for the lateral semiconductor device unit based on the post-fabrication plan data.

By way of non-limiting example, to determine a unit size for each lateral semiconductor device unit 106 of semiconductor wafer 100 (FIG. 1), post-fabrication plan data associated with a plurality of reference semiconductor wafers may be obtained. The reference semiconductor wafers may be similar to the semiconductor wafers described herein. For instance, each reference semiconductor wafer may include a plurality of reference semiconductor die having at least one reference semiconductor device unit. In some examples, the post-fabrication plan data may include dimensional measurements for each of the plurality of reference semiconductor die of the plurality of reference semiconductor wafers. Additionally and/or alternatively, in some examples, the post-fabrication plan data may further include data indicative of a defect density of each of the plurality of reference semiconductor wafers and/or a die yield of each of the plurality of reference semiconductor wafers. Based on this post-fabrication plan data, the unit size for each lateral semiconductor device unit 106 may then be determined. For instance, in some examples, the unit size for each lateral semiconductor device unit 106 may be substantially similar to a unit size of a smallest reference semiconductor die of the plurality of reference semiconductor die.

Referring to FIG. 10, at (404), the method 400 includes arranging a semiconductor wafer having a plurality of lateral semiconductor device units. Each of the plurality of lateral semiconductor device units may have the unit size determined at 402. By way of non-limiting example, after the unit size for the lateral semiconductor device unit 106 (FIG. 1) is determined, a plurality of lateral semiconductor device units 106 each having the unit size may be arranged on the semiconductor wafer 100 (FIG. 1).

Referring to FIG. 10, at (406), the method 400 includes determining one or more dimensions for a plurality of semiconductor die. Each of the plurality of semiconductor die may include at least one lateral semiconductor device unit. To determine the one or more dimensions for the plurality of semiconductor die, the method 400 may include obtaining data indicative of one or more rejected lateral semiconductor device units of the plurality of lateral semiconductor device units and data associated with a plurality of reference semiconductor wafers and, then, determining the one or more dimensions for the plurality of semiconductor die based on the data indicative of the one or more rejected lateral semiconductor device units and the data associated with the plurality of reference semiconductor wafers. In some examples, the one or more dimensions for the plurality of semiconductor die may also be determined based on an estimated defect density and an estimated die yield for the semiconductor wafer.

By way of non-limiting example, to determine the one or more dimensions for the plurality of semiconductor die 250 (FIGS. 7A-7F), data indicative of one or more rejected lateral semiconductor device units 106′ (FIG. 1) may be obtained by testing the semiconductor wafer 100 (FIG. 1). Based on such reliability tests, an estimated defect density and an estimated die yield for the semiconductor wafer 100 may be determined. Furthermore, data associated with a plurality of reference semiconductor wafers may also be obtained. As described above, the reference semiconductor wafers may be similar to the semiconductor wafers described herein. For instance, each reference semiconductor wafer may include a plurality of reference semiconductor die having at least one reference semiconductor device unit. In some examples, the data associated with the plurality of reference semiconductor wafers may include data indicative of a defect density of each of the plurality of reference semiconductor wafers. Additionally and/or alternatively, in some examples, the data associated with the plurality of reference semiconductor wafers may include data indicative of a die yield of each of the plurality of reference semiconductor wafers. Hence, the one or more dimensions for the plurality of semiconductor die 250 may be determined based on the rejected lateral semiconductor device units 106′, the estimated defect density and estimated die yield of the semiconductor wafer 100, and the data associated with the plurality of reference semiconductor wafers.

Referring to FIG. 10, at (408), the method 400 includes determining one or more cut lines for the semiconductor wafer based on the one or more dimensions for the plurality of semiconductor die (e.g., determined at (406)). As described herein, the one or more cut lines, which group the plurality of lateral semiconductor device units into the plurality of semiconductor die, may define one or more non-metal regions of the semiconductor wafer. By way of non-limiting example, as described above, the one or more cut lines 110 (FIGS. 1, 7A-7F) may group the plurality of lateral semiconductor device units 106 (FIG. 1) into the plurality of semiconductor die 250 (FIGS. 7A-7F). As such, the one or more cut lines 110 for the semiconductor wafer 100 (FIG. 1) may determined based on the one or more dimensions for the plurality of semiconductor die 250 (FIGS. 7A-7F) (e.g., determined at (406)).

Referring to FIG. 10, at (410), the method 400 includes cutting the semiconductor wafer into the plurality of semiconductor die along the one or more cut lines. The semiconductor wafer may be cut using, for instance, a laser-based cutting process and/or a saw-based cutting process. By way of non-limiting example, the semiconductor wafer 100 (FIG. 1) may be cut into a plurality of semiconductor die 250 (FIGS. 7A-7F) along the one or more cut lines 110. In some examples, as described above, the semiconductor wafer 100 may be cut into a plurality of semiconductor die 250 having different sizes, shapes, dimensions, numbers of lateral semiconductor device units 106, etc. As such, by cutting varying semiconductor die 250 from the semiconductor wafer 100, a die yield of the semiconductor wafer 100 may be increased, while the material waste associated with the fabrication method 400 may be decreased.

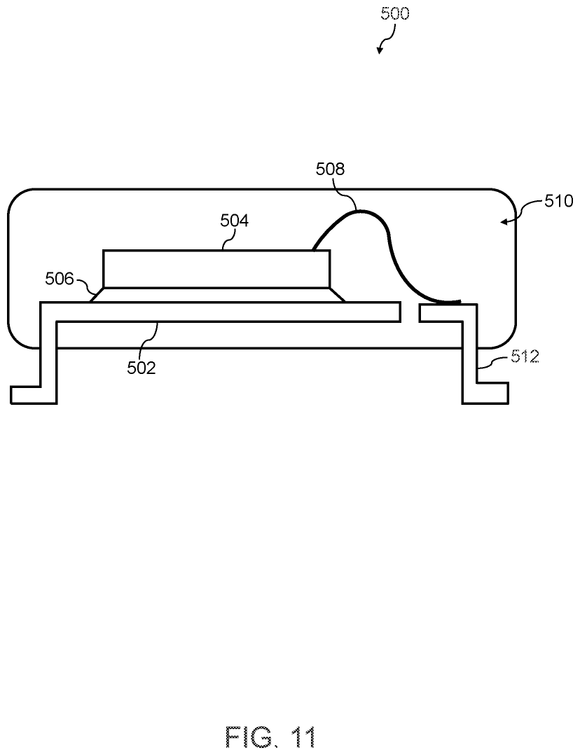

FIG. 11 depicts an example semiconductor package 500 of a semiconductor device according to example embodiments of the present disclosure. The semiconductor package 500 may be, for instance, a discrete semiconductor package. FIG. 11 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 11 is intended to represent structures for identification and description and is not intended to represent the structures to physical scale.

As shown, the semiconductor package 500 may include a conductive submount 502 (e.g., a patterned conductive substrate, lead frame, clip structure or other power substrate) on which a semiconductor die 504 containing one or more power devices (e.g., transistors, diodes, etc.) is attached using a die-attach material 506. It should be understood that the semiconductor die 504 may correspond to any of the semiconductor die disclosed herein and may be fabricated using any of the methods disclosed herein.

The die-attach material 506 may provide a thermal, mechanical, and electrical connection between the semiconductor die 504 and the conductive submount 502. In some examples, the semiconductor die 504 may also be connected to the conductive submount 502 using wire bonds 508. An encapsulating material 510 (e.g., epoxy mold compound (EMC)) may fill the space around the semiconductor die 504 and the submount 502, thereby forming a housing. The semiconductor package 500 may further include one or more connection structures, such as electrical leads 512, that extend outward from the housing (e.g., outward from the encapsulating material 510).

The semiconductor package 500 may include one or more metallization structures, such as any of the metallization structures disclosed herein. More particularly, the semiconductor die 504 may include one or more metallization structures, such as bonding pads. The bonding pads may be coupled to the one or more electrical leads 512 using the wire bonds 508. The wire bonds 508 may be aluminum and/or copper. The wire bonds 508 may have a thickness of about 15 mil to about 20 mil (e.g., about 381 μm to about 508 μm). As noted above, the bonding pads may have a thickness, for instance, of about 4 μm or less. A backside metallization layer on the semiconductor die 504 may be coupled to the submount 502 (e.g., lead frame) using, for instance, the die-attach material 506. The encapsulating material 510 may encapsulate the semiconductor die 504, including its metallization structures, wire bonds 508, submount 502, and other portions of the semiconductor package 500. In some examples, the encapsulating material 510 may directly contact the metallization structures (e.g., bonding pads, backside metallization layer, etc.) of the semiconductor package 500.

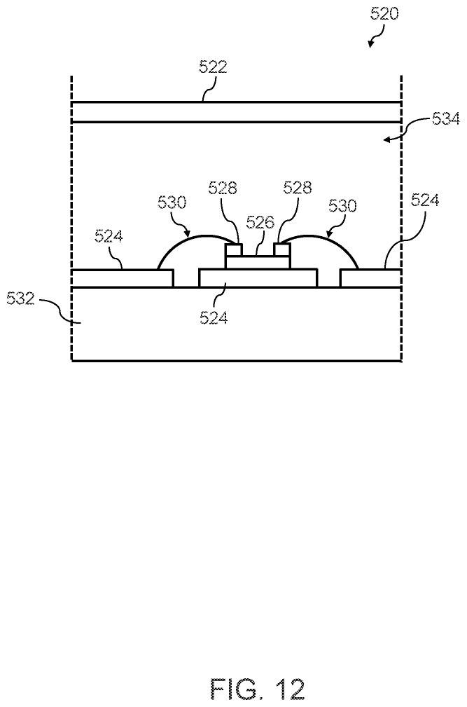

FIG. 12 depicts a cross-sectional view of an example semiconductor package of a semiconductor device 520 according to example embodiments of the present disclosure. The semiconductor device 520 of FIG. 12 is a portion of a power module. FIG. 12 is intended to represent structures for identification and description and is not intended to represent the structures to physical scale. The semiconductor device 520 may include a housing 522. The semiconductor device 520 may include a conductive submount 524 (e.g., a patterned conductive submount) on which a semiconductor die 526 is mounted (e.g., using a die-attach material). It should be understood that the semiconductor die 526 may correspond to any of the semiconductor die disclosed herein and may be fabricated using any of the methods disclosed herein. For instance, the semiconductor die 526 may be mounted on submount 524 using a die-attach material that includes a sintered material, such as sintered silver and/or sintered copper. The semiconductor die 526 may include one or more metallization structures, such as bonding pads 528. In some embodiments, the semiconductor die 526 may be connected to the conductive submount 524 using wire bonds 530. The conductive submount 524 may be mounted on a base layer 532 (e.g., an insulating layer). An inert gel 534 may fill the space between the semiconductor die 526 and the housing 522.

FIGS. 10-11 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

One example aspect of the present disclosure is directed to a method. The method includes providing a semiconductor wafer comprising a plurality of lateral semiconductor device units. The method further includes determining one or more cut lines for the semiconductor wafer. The one or more cut lines group the plurality of lateral semiconductor device units into a plurality of semiconductor die, and a first semiconductor die of the plurality of semiconductor die has a different size relative to a second semiconductor die of the plurality of semiconductor die.

In some examples, determining the one or more cut lines for the semiconductor wafer includes obtaining data indicative of one or more rejected lateral semiconductor device units and determining the one or more cut lines based at least in part on the data indicative of one or more rejected lateral semiconductor device units.

In some examples, determining the one or more cut lines for the semiconductor wafer includes obtaining data indicative of a defect density of the semiconductor wafer, determining a die yield of the semiconductor wafer based on the data indicative of the defect density of the semiconductor wafer, and determining the one or more cut lines based at least in part on the data indicative of the defect density of the semiconductor wafer and the die yield of the semiconductor wafer.

In some examples, the method further includes cutting the semiconductor wafer into the plurality of semiconductor die along the one or more cut lines.

In some examples, the one or more cut lines define one or more non-metal regions of the semiconductor wafer.

In some examples, cutting the semiconductor wafer into the plurality of semiconductor die includes cutting the semiconductor wafer into the plurality of semiconductor die with a laser-based cutting process.

In some examples, cutting the semiconductor wafer into the plurality of semiconductor die includes cutting the semiconductor wafer into the plurality of semiconductor die with a saw-based cutting process.

In some examples, the first semiconductor die includes a single lateral semiconductor device unit and the second semiconductor die includes two or more lateral semiconductor device units.

In some examples, the first semiconductor die includes two or more semiconductor device units and the second semiconductor die includes two or more semiconductor device units, and the first semiconductor die includes a different number of semiconductor device units relative to the second semiconductor die.

In some examples, the first semiconductor die has a rectangular shape and the second semiconductor die has a rectangular shape.

In some examples, the first semiconductor die has a rectangular shape and the second semiconductor die has a non-rectangular shape.

In some examples, each of the plurality of lateral semiconductor device units is associated with a blocking voltage, and the blocking voltage associated with the first semiconductor die is substantially the same as the blocking voltage associated with the second semiconductor die.

In some examples, an on-resistance associated with the first semiconductor die is different from an on-resistance associated with the second semiconductor die.

In some examples, each lateral semiconductor device unit includes a plurality of semiconductor device cells.

In some examples, each semiconductor device cell includes a source contact, a drain contact, and a gate contact arranged on a first side of a semiconductor structure.

In some examples, the drain contact is at least partially interdigitated with the source contact.

In some examples, the gate contact at least partially surrounds the source contact.

In some examples, the semiconductor structure includes a wide bandgap semiconductor structure.

In some examples, the semiconductor structure includes silicon carbide or a Group Ill-nitride.

In some examples, each lateral semiconductor device unit includes a lateral silicon carbide-based MOSFET or a silicon carbide-based Schottky diode.

Another example aspect of the present disclosure is directed to a semiconductor die. The semiconductor die includes a plurality of lateral semiconductor device units. The semiconductor die further includes one or more uncut scribe lines between each of the plurality of lateral semiconductor device units. The one or more uncut scribe lines each include a non-metal region.

In some examples, the plurality of lateral semiconductor device units are arranged in a rectangular array on the semiconductor die.

In some examples, the rectangular array includes at least four lateral semiconductor device units.

In some examples, the rectangular array includes at least six lateral semiconductor device units.

In some examples, the rectangular array includes at least nine lateral semiconductor device units.

In some examples, the plurality of lateral semiconductor device units are arranged in a non-rectangular array on the semiconductor die.

In some examples, each lateral semiconductor device unit includes a plurality of semiconductor device cells.

In some examples, each semiconductor device cell includes a source contact, a drain contact, and a gate contact arranged on a first side of a semiconductor structure.

In some examples, the drain contact is at least partially interdigitated with the source contact.

In some examples, the gate contact at least partially surrounds the source contact.

In some examples, the semiconductor structure includes a wide bandgap semiconductor structure.

In some examples, the semiconductor structure includes silicon carbide or a Group Ill-nitride.

In some examples, each lateral semiconductor device unit includes a lateral silicon carbide-based MOSFET or a silicon carbide-based Schottky diode.

Another example aspect of the present disclosure is directed to a method. The method includes providing a semiconductor wafer having a plurality of lateral semiconductor device units. The method further includes determining one or more cut lines for the semiconductor wafer. The one or more cut lines group the plurality of lateral semiconductor device units into a plurality of semiconductor die, and a first semiconductor die of the plurality semiconductor has a different number of lateral semiconductor device units relative to a second semiconductor die of the plurality of semiconductor die.

In some examples, determining the one or more cut lines for the semiconductor wafer includes obtaining data indicative of one or more rejected lateral semiconductor device units and determining the one or more cut lines based at least in part on the data indicative of one or more rejected lateral semiconductor device units.

In some examples, determining the one or more cut lines for the semiconductor wafer includes obtaining data indicative of a defect density of the semiconductor wafer, determining a die yield of the semiconductor wafer based on the data indicative of the defect density of the semiconductor wafer, and determining the one or more cut lines based at least in part on the data indicative of the defect density of the semiconductor wafer and the die yield of the semiconductor wafer.

In some examples, the method further includes cutting the semiconductor wafer into the plurality of semiconductor die along the one or more cut lines.

In some examples, the one or more cut lines define one or more non-metal regions of the semiconductor wafer.

In some examples, cutting the semiconductor wafer into the plurality of semiconductor die includes cutting the semiconductor wafer into the plurality of semiconductor die with a laser-based cutting process.

In some examples, cutting the semiconductor wafer into the plurality of semiconductor die includes cutting the semiconductor wafer into the plurality of semiconductor die with a saw-based cutting process.

In some examples, the first semiconductor die includes a single lateral semiconductor device unit and the second semiconductor die includes two or more lateral semiconductor device units.

In some examples, the first semiconductor die includes two or more semiconductor device units and the second semiconductor die includes two or more semiconductor device units, and the first semiconductor die includes a different number of semiconductor device units relative to the second semiconductor die.

In some examples, the first semiconductor die has a rectangular shape and the second semiconductor die has a rectangular shape.

In some examples, the first semiconductor die has a rectangular shape and the second semiconductor die has a non-rectangular shape.

In some examples, each of the plurality of lateral semiconductor device units is associated with a blocking voltage, and the blocking voltage associated with the first semiconductor die is substantially the same as the blocking voltage associated with the second semiconductor die.

In some examples, an on-resistance associated with the first semiconductor die is different from an on-resistance associated with the second semiconductor die.

In some examples, each lateral semiconductor device unit includes a plurality of semiconductor device cells.

In some examples, each semiconductor device cell includes a source contact, a drain contact, and a gate contact arranged on a first side of a semiconductor structure.

In some examples, the drain contact is at least partially interdigitated with the source contact.

In some examples, the gate contact at least partially surrounds the source contact.

In some examples, semiconductor structure includes a wide bandgap semiconductor structure.

In some examples, the semiconductor structure includes silicon carbide or a Group Ill-nitride.

In some examples, each lateral semiconductor device unit includes a lateral silicon carbide-based MOSFET or a silicon carbide-based Schottky diode.

Another example aspect of the present disclosure is directed to a method. The method includes determining a unit size for a lateral semiconductor device unit. The method further includes arranging a semiconductor wafer having a plurality of lateral semiconductor device units, each of the plurality of lateral semiconductor device units having the unit size. The method further includes determining one or more dimensions for a plurality of semiconductor die, each of the plurality of semiconductor die having at least one lateral semiconductor device unit.

In some examples, determining the unit size for the lateral semiconductor device unit includes obtaining post-fabrication plan data associated with a plurality of reference semiconductor wafers, each reference semiconductor wafer including a plurality of reference semiconductor die, the post-fabrication plan data including dimensional measurements for each of the plurality of reference semiconductor die; and determining the unit size for the lateral semiconductor device unit based on the post-fabrication plan data.

In some examples, the post-fabrication plan data further includes data indicative of a defect density of each of the plurality of reference semiconductor wafers.

In some examples, the post-fabrication plan data further includes data indicative of a die yield of each of the plurality of reference semiconductor wafers.

In some examples, the unit size for the lateral semiconductor device unit is substantially similar to a unit size of a smallest reference semiconductor die of the plurality of reference semiconductor die.

In some examples, determining the one or more dimensions for the plurality of semiconductor die includes obtaining data indicative of one or more rejected lateral semiconductor device units of the plurality of lateral semiconductor device units, obtaining data associated with a plurality of reference semiconductor wafers, each of the plurality of reference semiconductor wafers comprising a plurality of reference semiconductor die, and determining the one or more dimensions for the plurality of semiconductor die based on the data indicative of the one or more rejected lateral semiconductor device units and the data associated with the plurality of reference semiconductor wafers.

In some examples, the data associated with the plurality of reference semiconductor wafers includes data indicative of a defect density of each of the plurality of reference semiconductor wafers.

In some examples, the data associated with the plurality of reference semiconductor wafers includes data indicative of a die yield of each of the plurality of reference semiconductor wafers.

In some examples, determining the one or more dimensions for the plurality of semiconductor die further includes determining an estimated defect density for the semiconductor wafer, determining an estimated die yield for the semiconductor wafer, and determining the one or more dimensions for the plurality of semiconductor die based on the data indicative of the one or more rejected lateral semiconductor device units, the data associated with the plurality of reference semiconductor wafers, the estimated defect density of the semiconductor wafer, and the estimated die yield of the semiconductor wafer.

In some examples, the method further includes determining one or more cut lines for the semiconductor wafer based on the one or more dimensions for the plurality of semiconductor die and cutting the semiconductor wafer into the plurality of semiconductor die along the one or more cut lines.

In some examples, the one or more cut lines define one or more non-metal regions of the semiconductor wafer.

In some examples, cutting the semiconductor wafer into the plurality of semiconductor die includes cutting the semiconductor wafer into the plurality of semiconductor die with a laser-based cutting process.

In some examples, cutting the semiconductor wafer into the plurality of semiconductor die includes cutting the semiconductor wafer into the plurality of semiconductor die with a saw-based cutting process.

In some examples, cutting the semiconductor wafer into the plurality of semiconductor die includes cutting the semiconductor wafer into a first semiconductor die of the plurality of semiconductor die and cutting the semiconductor wafer into a second semiconductor die of the plurality of semiconductor die, wherein the first semiconductor die has a different size relative to the second semiconductor die.

In some examples, the one or more cut lines group the plurality of lateral semiconductor device units into the plurality of semiconductor die.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method, comprising:
providing a semiconductor wafer comprising a plurality of lateral semiconductor device units; and
determining one or more cut lines for the semiconductor wafer,
wherein the one or more cut lines group the plurality of lateral semiconductor device units into a plurality of semiconductor die, wherein a first semiconductor die of the plurality of semiconductor die has a different size relative to a second semiconductor die of the plurality of semiconductor die.

2. The method of claim 1, wherein determining the one or more cut lines for the semiconductor wafer comprises:
obtaining data indicative of one or more rejected lateral semiconductor device units; and
determining the one or more cut lines based at least in part on the data indicative of one or more rejected lateral semiconductor device units.

3. The method of claim 1, wherein determining the one or more cut lines for the semiconductor wafer comprises:
obtaining data indicative of a defect density of the semiconductor wafer;
determining a die yield of the semiconductor wafer based on the data indicative of the defect density of the semiconductor wafer; and
determining the one or more cut lines based at least in part on the data indicative of the defect density of the semiconductor wafer and the die yield of the semiconductor wafer.

4. The method of claim 1, further comprising cutting the semiconductor wafer into the plurality of semiconductor die along the one or more cut lines, wherein the one or more cut lines define one or more non-metal regions of the semiconductor wafer.

5. The method of claim 1, wherein the first semiconductor die comprises two or more semiconductor device units and the second semiconductor die comprises two or more semiconductor device units, wherein the first semiconductor die comprises a different number of semiconductor device units relative to the second semiconductor die.

6. The method of claim 1, wherein the first semiconductor die has a rectangular shape and the second semiconductor die has one of a rectangular shape or a non-rectangular shape.

7. The method of claim 1, wherein each lateral semiconductor device unit comprises a lateral silicon carbide-based MOSFET or a silicon carbide-based Schottky diode.

8. A semiconductor die, comprising:
a plurality of lateral semiconductor device units; and
one or more uncut scribe lines between each of the plurality of lateral semiconductor device units, the one or more uncut scribe lines each comprising a non-metal region.

9. The semiconductor die of claim 8, wherein the plurality of lateral semiconductor device units are arranged in one of a rectangular array or a non-rectangular array on the semiconductor die.

10. The semiconductor die of claim 8, wherein each lateral semiconductor device unit comprises a plurality of semiconductor device cells, and wherein each semiconductor device cell comprises a source contact, a drain contact, and a gate contact arranged on a first side of a semiconductor structure.

11. The semiconductor die of claim 10, wherein the semiconductor structure comprises a wide bandgap semiconductor structure, the wide bandgap semiconductor structure comprising silicon carbide or a Group III-nitride.

12. A method, comprising:
determining a unit size for a lateral semiconductor device unit;
arranging a semiconductor wafer comprising a plurality of lateral semiconductor device units, each of the plurality of lateral semiconductor device units having the unit size; and
determining one or more dimensions for a plurality of semiconductor die, each of the plurality of semiconductor die comprising at least one lateral semiconductor device unit.

13. The method of claim 12, wherein determining the unit size for the lateral semiconductor device unit comprises:
obtaining post-fabrication plan data associated with a plurality of reference semiconductor wafers, each reference semiconductor wafer comprising a plurality of reference semiconductor die, the post-fabrication plan data comprising dimensional measurements for each of the plurality of reference semiconductor die; and
determining the unit size for the lateral semiconductor device unit based on the post-fabrication plan data.

14. The method of claim 13, wherein the post-fabrication plan data further comprises data indicative of a defect density of each of the plurality of reference semiconductor wafers and data indicative of a die yield of each of the plurality of reference semiconductor wafers, and wherein the unit size for the lateral semiconductor device unit is substantially similar to a unit size of a smallest reference semiconductor die of the plurality of reference semiconductor die.

15. The method of claim 14, wherein determining the one or more dimensions for the plurality of semiconductor die comprises:
obtaining data indicative of one or more rejected lateral semiconductor device units of the plurality of lateral semiconductor device units;
obtaining data associated with a plurality of reference semiconductor wafers, each of the plurality of reference semiconductor wafers comprising a plurality of reference semiconductor die; and
determining the one or more dimensions for the plurality of semiconductor die based on the data indicative of the one or more rejected lateral semiconductor device units and the data associated with the plurality of reference semiconductor wafers.

16. The method of claim 15, wherein the data associated with the plurality of reference semiconductor wafers comprises one of data indicative of a defect density of each of the plurality of reference semiconductor wafers or data indicative of a die yield of each of the plurality of reference semiconductor wafers.

17. The method of claim 15, wherein determining the one or more dimensions for the plurality of semiconductor die further comprises:
determining an estimated defect density for the semiconductor wafer;
determining an estimated die yield for the semiconductor wafer; and
determining the one or more dimensions for the plurality of semiconductor die based on the data indicative of the one or more rejected lateral semiconductor device units, the data associated with the plurality of reference semiconductor wafers, the estimated defect density of the semiconductor wafer, and the estimated die yield of the semiconductor wafer.

18. The method of claim 12, further comprising:
determining one or more cut lines for the semiconductor wafer based on the one or more dimensions for the plurality of semiconductor die; and
cutting the semiconductor wafer into the plurality of semiconductor die along the one or more cut lines,
wherein the one or more cut lines define one or more non-metal regions of the semiconductor wafer.

19. The method of claim 18, wherein cutting the semiconductor wafer into the plurality of semiconductor die comprises cutting the semiconductor wafer into the plurality of semiconductor die with one of a laser-based cutting process or a saw-based cutting process.

20. The method of claim 18, wherein cutting the semiconductor wafer into the plurality of semiconductor die comprises:
cutting the semiconductor wafer into a first semiconductor die of the plurality of semiconductor die; and
cutting the semiconductor wafer into a second semiconductor die of the plurality of semiconductor die,
wherein the first semiconductor die has a different size relative to the second semiconductor die.
